(19) United States
(12) Patent Application Publication
(10) Pub. No.: US 2026/0114301 A1
(43) Pub. Date: Apr. 23, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventor: HUNG-TE LIN, HSINCHU COUNTY (TW)

(21) Appl. No.: 18/923,747

(22) Filed: Oct. 23, 2024

(51) Int. Cl. H01L 23/498; H01L 21/265; H01L 21/48; H01L 21/683; H01L 23/00; H01L 23/14; H01L 25/065

(52) U.S. Cl. CPC H10W 70/635; H10P 30/20; H10P 72/74; H10W 70/095; H10W 70/65; H10W 70/69; H10W 72/0198; H10W 90/00; H10W 90/724

(57) ABSTRACT

A semiconductor structure includes a substrate, an interconnect structure, a first via structure and a second via structure is provided. The substrate includes a first surface and a second surface opposite to the first surface, wherein the substrate includes a first semiconductor portion and a second semiconductor portion different from the first semiconductor portion. The interconnect structure is over the first surface of the substrate. The first via structure penetrates the substrate from the first surface to the second surface, and is coupled to the interconnect structure. The second via structure penetrates the substrate from the first surface to the second surface, and is separated from the interconnect structure and the first via structure.

### BACKGROUND

In three-dimensional integrated circuit packaging, an interposer structure is used as an intermediate for electrically connecting a plurality of semiconductor chips or “dies”) with a substrate, so-called “chip-on-wafer-on-substrate,” for further chip package so as to decrease the area required for packaging the semiconductor chips, reduce power consumption and cost. The interposer structure with high heat dissipation and performance is desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor structure 200 in accordance with some embodiments of the present disclosure.

FIG. 2 illustrates a schematic plan view of the back side of the semiconductor structure 200 in accordance with some embodiments of the present disclosure.

FIG. 3 illustrates a schematic plan view of the front side of the semiconductor structure 200 in accordance with some embodiments of the present disclosure.

FIG. 4 illustrates a schematic plan view of the back side of the semiconductor structure 200 in accordance with some embodiments of the present disclosure.

FIG. 5 illustrates a partially enlarged cross-sectional view of the semiconductor structure 200 in accordance with some embodiments of the present disclosure.

FIG. 6 discloses a partially enlarged cross-sectional view of the semiconductor structure 200 in accordance with some embodiments of the present disclosure.

FIG. 7 discloses a plan view of the semiconductor structure 200 in accordance with some embodiments of the present disclosure.

FIG. 8 discloses a plan view of the semiconductor structure 200 in accordance with some embodiments of the present disclosure.

FIG. 9 illustrates a partially enlarged cross-sectional view of the semiconductor structure 200 in accordance with some embodiments of the present disclosure.

FIG. 10 illustrates a plan view of a back side of a semiconductor structure 1100 in accordance with some embodiments of the present disclosure.

FIG. 11A illustrates a cross-sectional view of a wafer-level view of a plurality of semiconductor structures 200 in accordance with some embodiments of the present disclosure.

FIG. 11B illustrates a plan view of a wafer-level view of a plurality of semiconductor structures 200 in accordance with some embodiments of the present disclosure.

FIGS. 12A to 12C each illustrate a partially enlarged cross-sectional view of the semiconductor structures A, B and C and their accompanying silicon/carbon/oxygen distribution in the substrate in accordance with some embodiments of the present disclosure.

FIG. 13 illustrates a cross-sectional view of a semiconductor structure 200 in accordance with some embodiments of the present disclosure.

FIG. 14 illustrates a cross-sectional and partial view of a semiconductor structure 1800 in accordance with some embodiments of the present disclosure.

FIG. 15 illustrates a plan views of the back side of semiconductor structure in accordance with some embodiments of the present disclosure.

FIG. 16 illustrates a plan views of the back side of semiconductor structure in accordance with some embodiments of the present disclosure.

FIG. 17 illustrates a plan view of the arrangement of the semiconductor structures 100 or 200 on a bottom substrate 1201 in accordance with some embodiments of the present disclosure.

FIGS. 18A and 18B illustrate plan views of the arrangement of the semiconductor structures 200 on a bottom substrate 1201 in accordance with some embodiments of the present disclosure.

FIG. 19 illustrates a flowchart of a method 1900 of forming a semiconductor structure in accordance with some embodiments of the present disclosure.

FIG. 20 illustrates a flowchart of a method 2000 of forming a semiconductor structure in accordance with some embodiments of the present disclosure.

FIGS. 21-1 to 21-25 illustrate cross-sectional views of a portion of a semiconductor structure at various stage of formation in accordance with some embodiments of the present disclosure.

FIG. 22 illustrates a cross-sectional view of a plurality of semiconductor substrates 200 disposed on a bottom substrate 1201 in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer or section from another. The terms such as “first”, “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

To meet the needs for semiconductor products with more functions, fast operation speeds and low power consumption, it is desired that more semiconductor chips of different functions be packed in a single gadget or computer. To decrease the overall packaging size of the semiconductor chips, a three-dimensional (“3D”) integrated circuit packaging technology, so-called “chip-on-wafer-on-substrate technology” is developed. The chip-on-wafer-on-substrate technology requires an interposer structure to electrically connect a plurality of semiconductor chips (or “dies”) with a substrate so as to decrease the area required for packaging the semiconductor chips. During operation of the 3D integrated circuit including an interposer structure, reduction of power consumption and cost is desired.

The present disclosure therefore provides a semiconductor structure and a method for forming the same. In some embodiments, the semiconductor structure may be an interposer structure for use in three-dimensional (“3D”) integrated circuit packaging as an intermediate for electrically connecting a plurality of semiconductor chips (or “dies”) with a substrate, for further chip package so as to decrease the area required for packaging the semiconductor chips, reduce power consumption and cost. In some embodiments, the semiconductor structure includes a thin substrate, which leads to lower through-silicon-via (TSV) resistance and higher performance. In some embodiments, the semiconductor structure includes additional via structures so as to increase overall heat dissipation.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

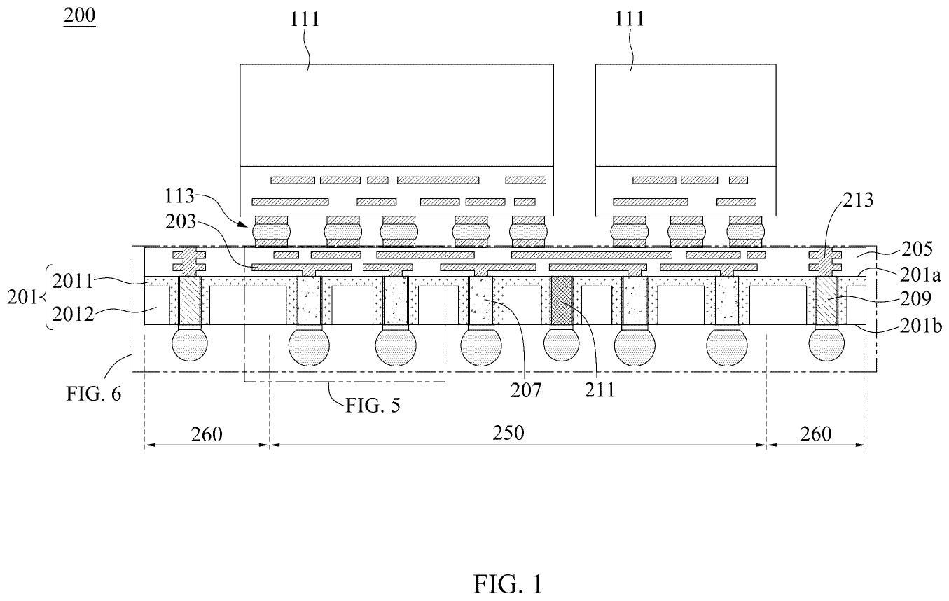

Refer to FIG. 1. FIG. 1 illustrates a schematic cross-sectional view of a semiconductor structure 200 in accordance with some embodiments of the present disclosure. In some embodiments, the semiconductor structure 200 may include a substrate 201, an interconnect structure 203, a first via structure 207 and a second via structure 209. In some embodiments, the substrate 201 may include a first surface 201a and a second surface 201b opposite to the first surface 201a. In some embodiments, the substrate 201 may include a first semiconductor portion 2011 and a second semiconductor portion 2012 different from the first semiconductor portion 2011. In some embodiments, the interconnect structure 203 is disposed over the first surface 201a of the substrate 201. In some embodiments, the first via structure 207 may penetrate the substrate 201 from the first surface 2011 to the second surface 2012, and may be coupled to the interconnect structure 203. In some embodiments, the second via structure 209 may penetrate the substrate 201 from the first surface 2011 to the second surface 2012, and may be separated from the interconnect structure 203 and the first via structure 207.

In some embodiments, a Moh's hardness of the second semiconductor portion 2012 may have greater than a Moh's hardness of the first semiconductor portion 2011. In some embodiments, the Moh's hardness of the second semiconductor portion 2012 may be about 1.4 times of that of the first semiconductor portion 2011. In some embodiments, the second semiconductor portion 2012 may have a Moh's hardness of about 9.5 and the first semiconductor portion 2011 may have a Moh's hardness of about 7. In some embodiments, a thermal conductivity of the second semiconductor portion 2012 is greater than that of the first semiconductor portion 2011. In some embodiments, the thermal conductivity of the second semiconductor portion 2012 may be about 3.3 times of that of the first semiconductor portion 2011. In some embodiments, the first semiconductor portion 2011 may have a thermoconductivity of about 1.5 W/cm ° C. In some embodiments, the second semiconductor portion 2012 may have a thermoconductivity of about 4.9 W/cm ° C. In some embodiments, the first semiconductor portion 2011 may have an energy gap of about 1.12 ev. In some embodiments, the second semiconductor portion 2012 may have an energy gap of about 2.2 ev. In some embodiments, the first semiconductor portion 2011 may include silicon. In some embodiments, the second semiconductor portion 2012 may include silicon carbide. In some embodiments, the semiconductor structure 201 may have a height H of about 1 to 10 micrometers.

In some embodiments, the second via structure 209 may be separated from the second semiconductor portion 2012 by the first semiconductor portion 2011. In some embodiments, a sidewall of the second via structure 209 is in direct contact with the first semiconductor portion 2011. In some embodiments, the first via structure 207 may be separated from the second semiconductor portion 2012 by the first semiconductor portion 2011. In some embodiments, a sidewall of the first via structure 207 is in direct contact with the first semiconductor portion 2011. In some embodiments, the first via structure 207 may be disposed in a central region 250 of the substrate 201, and the second via structure 209 may be disposed in a peripheral region 260 of the substrate 201.

In some embodiments, the semiconductor structure 200 may further include a third via structure 211 disposed in the central region 250 of the substrate 201. In some embodiments, the third via structure 211 may penetrate the substrate 201 from the first surface 201a to the second surface 201b. In some embodiments, the third via structure 211 may be separated from the first via structure 207 and the interconnect structure 203. In some embodiments, the third via structure 211 may be separated from the second via structure 209 as well.

In some embodiments, the semiconductor structure 200 may further include a second interconnect structure 213. In some embodiments, the second via structure 209 may be coupled to the second interconnect structure 213, wherein the second interconnect structure 213 is separated from the interconnect structure 203. In some embodiments, the second semiconductor portion 2012 is separated from the interconnect structure 203 by the first semiconductor portion 2011. In some embodiments, the first semiconductor portion 2011 is formed over a top surface of the second semiconductor portion 2012.

In some embodiments, the semiconductor structure 200 may further include at least one die 111 disposed over the first surface 201a of the substrate 201 and coupled to the interconnect structure 203. In some embodiments, the at least one die 111 may be connected to the interconnect structure 203 by at least one external connection feature 113 disposed between the interconnect structure 203 and the at least one die 111. In some embodiments, the at least one die 111 may be electrically connected to the first via structure 207 through the at least one external connection feature 113 and the interconnect structure 203. In some embodiments, the at least one die 111 is separated from the second via structure 209 and the second interconnect structure 213.

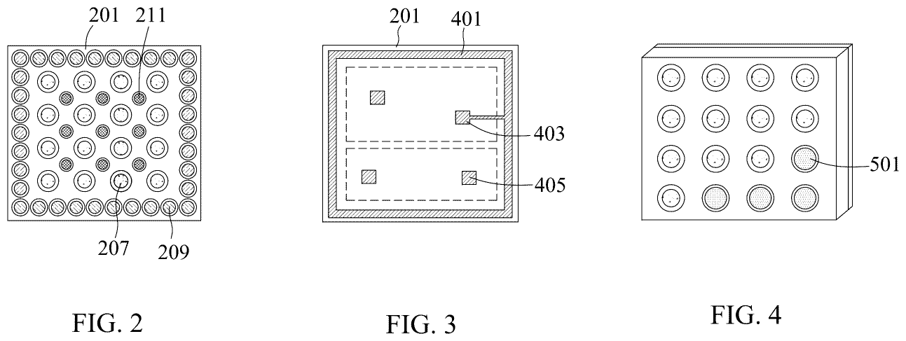

Refer to FIG. 2. FIG. 2 illustrates a schematic plan view of the back side of the semiconductor structure 200 in accordance with some embodiments of the present disclosure. In some embodiments, the semiconductor structure 200 may include a plurality of the first via structures 207, a plurality of the second via structures 209, and a plurality of the third via structures 211. In some embodiments, the plurality of the second via structures 209 may surround the periphery of the substrate 201. In some embodiments, the plurality of the first via structures 207 may be disposed in arrays in the central region 250 of the substrate 201. In some embodiments, the plurality of the third via structures 211 may be disposed in arrays in the central region 250 of the substrate 201. In some embodiments, each of the plurality of the first via structures 207 may have an exposed area greater than an exposed area of each of the plurality of the second via structures 209, and greater than an exposed area of each of the plurality of the third via structures 211. In some embodiments, the exposed area of the second via structure 209 and the exposed area of the third via structure 211 may be the same. In other embodiments, the exposed area of the second via structure 209, may be greater than the exposed area of the third via structure 211, as shown in FIG. 2. In some embodiments, the exposed area of each of the plurality of the first via structures 207, each of the plurality of the second via structures 209 and each of the plurality of the third via structures 211 are the same.

Refer to FIG. 3. FIG. 3 illustrates a schematic plan view of the front side of the semiconductor structure 200 in accordance with some embodiments of the present disclosure. In some embodiments, the plurality of the second via structures 209 are electrically connected by a conductive ring structure 401 surrounding the periphery of the substrate 201, wherein the conductive ring structure 401 may be disposed over the first surface 201a of the substrate 201. In some embodiments, the conductive ring structure 401 may be coupled to the second interconnect structure 213. In some embodiments, the conductive ring structure 401 may include a metal. In some embodiments, the conductive ring structure 401 may be connected to a dummy conductive structure 403 separated from the at least one die 111.

Refer to FIG. 4. FIG. 4 illustrates a schematic plan view of the back side of the semiconductor structure 200 in accordance with some embodiments of the present disclosure. In some embodiments, the first via structure 207 may be exposed at the second surface 201b of the substrate 201, and may be coupled to an external terminal 501 disposed on the second surface 201b of the substrate 201. In some embodiments, the second via structure 209 may be exposed through the second surface 201b of the substrate 201, and be coupled to an external terminal 501. In other embodiments, the exposed second via structure 209 may be free of the external terminal 501, as shown in FIG. 4. In some embodiments, the third via structure 211 may be exposed through the second surface 201b of the substrate 201, and be coupled to an external terminal 501. In other embodiments, the exposed third via structure 211 may be free of the external terminal 501. In some embodiments, a width or a diameter of the external terminal 501 coupled to the first via structure 207 may be greater than a width or a diameter of the external terminals 501 coupled to the second via structure 209, and/or greater than a width or a diameter of the external terminals 501 coupled to the third via structure 211.

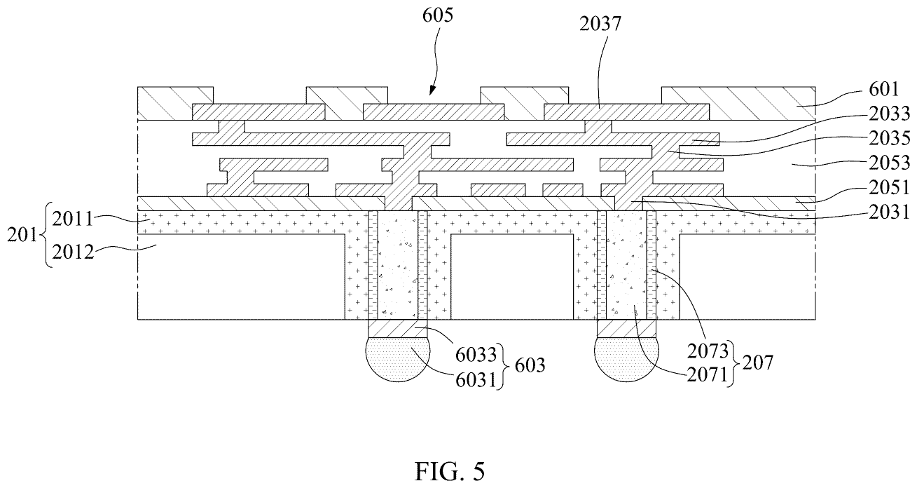

Refer to FIG. 5. FIG. 5 illustrates a partially enlarged cross-sectional view of the semiconductor structure 200 in accordance with some embodiments of the present disclosure. In some embodiments, the interconnect structure 203 of the semiconductor structure 200 is embedded in a first dielectric layer 2051 and a second dielectric layer 2053. In some embodiments, the interconnect structure 203 includes at least one contact feature 2031, a plurality of inter-conductive layers 2033, a plurality of inter-conductive vias 2035, and at least one top-conductive layer 2037. In some embodiments, the semiconductor structure 200 further includes a passivation layer 601. In some embodiments, the first dielectric layer 2051 is disposed on the first surface 201a of the substrate 201, and the second dielectric layer 2053 is disposed on the first dielectric layer 2051. In some embodiments, the plurality of inter-conductive layers 2033 and the plurality of inter-conductive vias 2035 are embedded in the second dielectric layer 2053. In some embodiments, the at least one top-conductive layer 2037 is disposed on the second dielectric layer 2053. In some embodiments, the passivation layer 601 is disposed on the at least one top-conductive layer 2037. In some embodiments, the passivation layer 601 is patterned so that a portion of the at least one top-conductive layer 2037 is exposed through a recess 605 to be coupled to the at least one external connection feature 113.

In some embodiment, an external terminal 603 is coupled to the first via structure 207, wherein the external terminal 603 includes a conductive film 6033 coupled to the first via structure 207 and a solder bump 6031 coupled to the conductive film 6033. In some embodiments, the external terminal 603 may include a microbump structure.

In some embodiments, the first via structure 207 may include a conductive material 2071 and a buffer layer 2073 over the sidewall of the first via structure 207. In some embodiments, the second via structure 209 and the third via structure 211 may have the same configuration as the first via structure 207. In some embodiments, at least one external connection feature 113 is coupled to the at least one top-conductive layer 2037. In some embodiments, the at least one contact feature 2031 are separated from each other by the first dielectric layer 2051. In some embodiments, the plurality of inter-conductive layers 2033 are connected by the inter-conductive vias 2035 disposed between them. In some embodiments, the top-conductive layer 2037 is electrically connected to the plurality of the first via structures 207 through the interconnect structure 203 coupled to the plurality of first via structure 207. In some embodiments, the semiconductor structure 200 may include a plurality of dies 111 and the electrical signals between the plurality of dies 111 are connected by the external connection feature 113 and the interconnect structure 203. In some embodiments, the dies 111 may be connected to other elements by the external connection feature 113, the interconnect structure 203 the first via structure 207 coupled to the interconnect structure 203, and the external terminal 603.

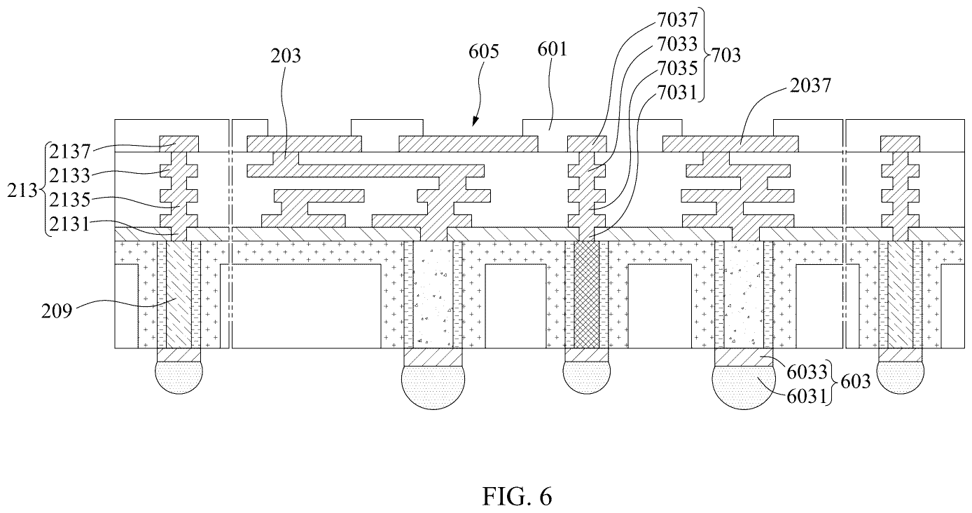

Refer to FIG. 6. FIG. 6 discloses a partially enlarged cross-sectional view of the semiconductor structure 200 in accordance with some embodiments of the present disclosure. In some embodiments, the second via structure 209 and third via structure 211 are arranged in the semiconductor structure 200 for heat dissipation. In some embodiments, the second interconnect structure 213 includes at least one second contact feature 2131, a plurality of second inter-conductive layers 2133, a plurality of second inter-conductive vias 2135, and a second top-conductive layer 2137.

In some embodiments, the semiconductor structure 200 may further include a third interconnect structure 703. In some embodiments, the at least one third via structure 211 is coupled to the third interconnect structure 703. In some embodiments, the at least one third via structure 211 is electrically connected to a dummy conductive structure 405 as shown in FIG. 3 by the third interconnect structure 703. In some embodiments, the third interconnect structure 703 includes at least one third contact feature 7031, a plurality of third inter-conductive layers 7033, a plurality of third inter-conductive vias 7035, and a third top-conductive layer 7037. In some embodiments, in the presence of the second via structure 209, the second interconnect structure 213, and the third via structure 211 and the third interconnect structure 703, the heat generated by operating the semiconductor structure 200 may be dissipated even more efficiently.

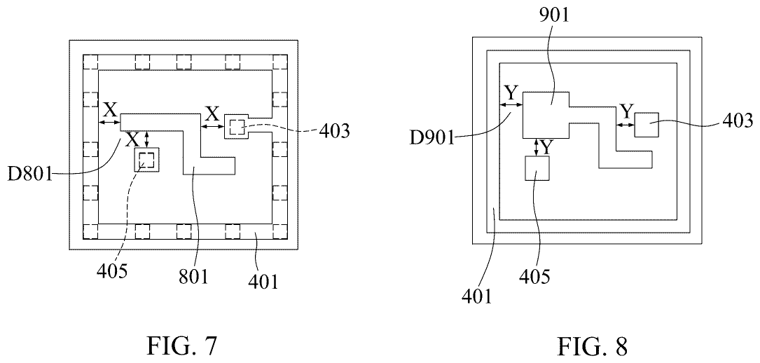

Refer to FIG. 7. FIG. 7 discloses a plan view of the semiconductor structure 200 in accordance with some embodiments of the present disclosure. In some embodiments, top surfaces of inter-conductive layers 2033 electrically connected to the at least one die 111 may have a shape 801. In some embodiments, at least a distance D801 may be present between the shape 801 and the dummy conductive structure 403 and 405, and at least a distance D801 may be present between the shape 801 and the conductive ring structure 401. In some embodiments, the distance D801 is greater than 0. In some embodiments, the distance D801 is 20 nm to 300 nm.

Refer to FIG. 8. FIG. 8 discloses a plan view of the semiconductor structure 200 in accordance with some embodiments of the present disclosure. In some embodiments, top surfaces of top-conductive layers 2037 electrically connected to the at least one die 111 may have a shape 901. In some embodiments, at least a distance D901 may be present between the shape 901 and the dummy conductive structure 403 and 405, and at least a distance D901 may be present between the shape 901 and the conductive ring structure 401. In some embodiments, the distance D901 is greater than 0. In some embodiments, the distance D901 is 0.5 μm to 5 μm.

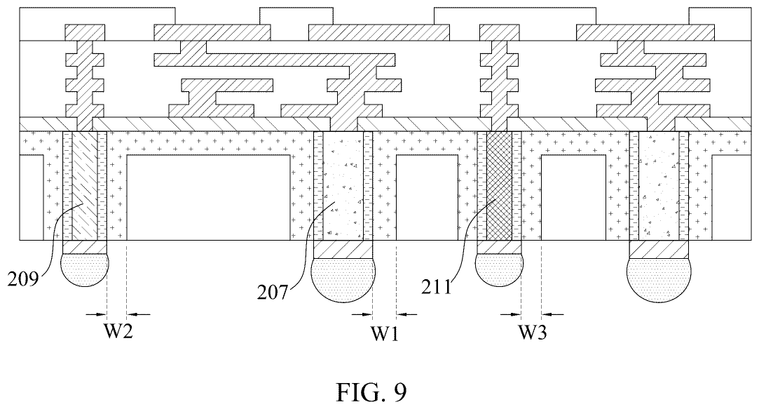

Refer to FIG. 9. FIG. 9 illustrates a partially enlarged cross-sectional view of the semiconductor structure 200 in accordance with some embodiments of the present disclosure. In some embodiments, the first via structure 207 is separated from the second semiconductor portion 2012 by the first semiconductor portion 2011 having a width W1. In some embodiments, W1 is greater than zero. In some embodiments, W1 is of 0.5 μm to 5 μm. In some embodiments, the second via structure 209 is separated from the second semiconductor portion 2012 by the first semiconductor portion 2011 having a width W2. In some embodiments, W2 is greater than zero. In some embodiments, W2 is of 0.5 μm to 5 μm. In some embodiments, the third via structure 211 is separated from the second semiconductor portion 2012 by the first semiconductor portion 2011 having a width W3. In some embodiments, W3 is greater than zero. In some embodiments, W3 is of 0.5 μm to 5 μm. The presence of first semiconductor portion 2011 between the second semiconductor portion 2012 and the first via structure 207, the second via structure 209 or the third via structure 211 facilitates the production of the aforementioned via structures during the manufacturing of the semiconductor structure 200.

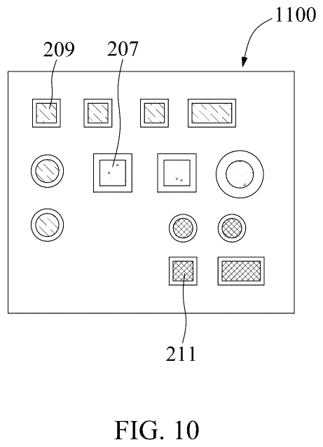

Refer to FIG. 10. FIG. 10 illustrates a plan view of a back side of a semiconductor structure 1100 in accordance with some embodiments of the present disclosure. In some embodiments, the cross-sectional shape of the first via structure 207, the second via structure 209 or the third via structure 211 may be a circle. In some embodiments, the cross-sectional shape of the first via structure 207, the second via structure 209 or the third via structure 211 may be a rectangle. In some embodiments, the cross-sectional shape of the first via structure 207, the second via structure 209 or the third via structure 211 may be a square. The shape of the first via structure 207, the second via structure 209 and the third via structure 211 may be the same or different from each other.

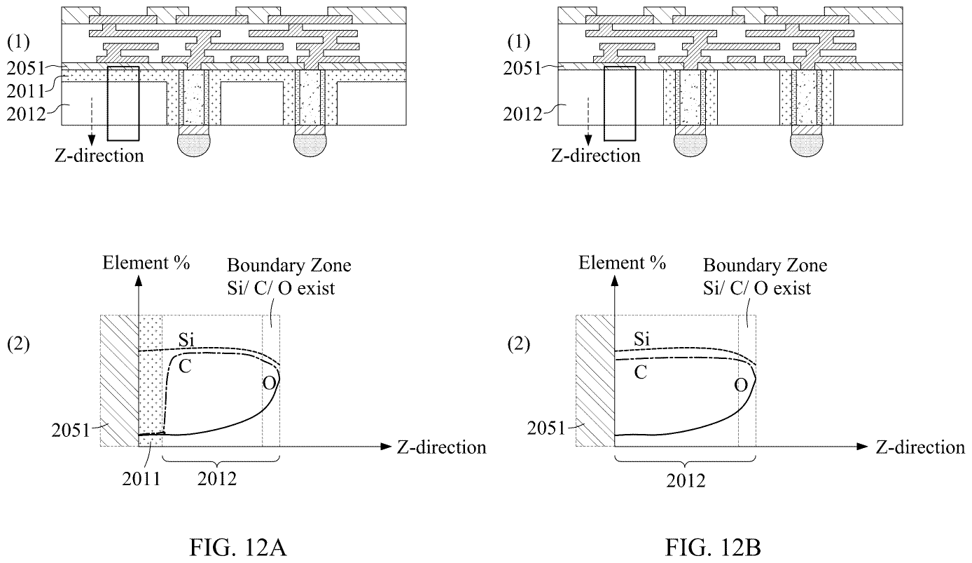

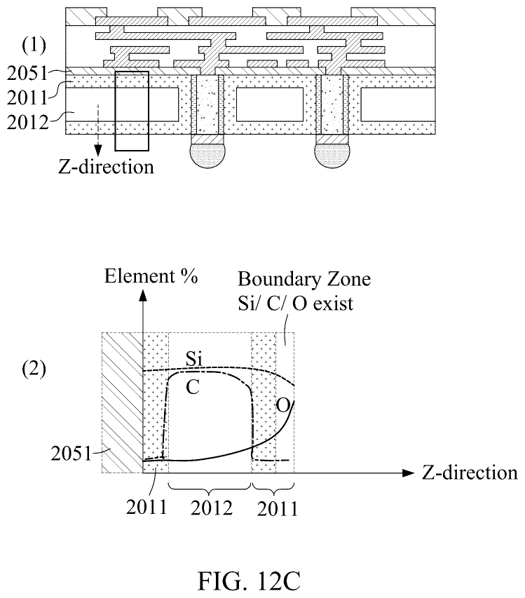

Refer to FIGS. 12A to 12C. FIGS. 12A to 12C each illustrate a partially enlarged cross-sectional view of the semiconductor structures A, B and C and their accompanying silicon/carbon/oxygen distribution in the substrate in accordance with some embodiments of the present disclosure. In some embodiments, a dielectric layer 1203 may be disposed over the second surface 201b of the substrate 201. The dielectric layer 1203 may horizontally cover portions of the second surfaces 201b of the substrate 201. In some embodiments, the first semiconductor portion 2011 includes a first semiconductor material, and the first semiconductor material includes silicon. In some embodiments, the second semiconductor portion 2012 includes a second semiconductor material, and the semiconductor material includes silicon and carbon, and the dielectric layer 1203 includes silicon and oxygen. In some embodiments, the silicon/carbon/oxygen distribution in the substrate 201 from the first surface 201a of the substrate 201 to the second surface 201b of the substrate 201 and the dielectric layer 1203 is as shown in each of the diagrams in FIGS. 12A to 12C from left to right. In some embodiments, the second semiconductor portion 2012 is in contact with the interconnect structure 203, as shown in FIG. 12A. In some embodiments, the second semiconductor portion 2012 is exposed through the second surface 201b of the substrate 201. In some embodiments, in the semiconductor structure A, the second semiconductor portion 2012 is in contact with the dielectric layer 1203. In some embodiments, in the semiconductor structure B, a top surface of the second semiconductor portion 2012 is in contact with the first dielectric layer 2051, as shown in FIG. 12B. In some embodiments, in the semiconductor structure C, the first semiconductor portion 2011 is in contact with the first dielectric layer 2051 and the dielectric layer 1203. In some embodiments, in the semiconductor structure C, a top surface and a bottom surface of the second semiconductor portion 2012 are in contact with the first semiconductor portion 2011, as shown in FIG. 12C.

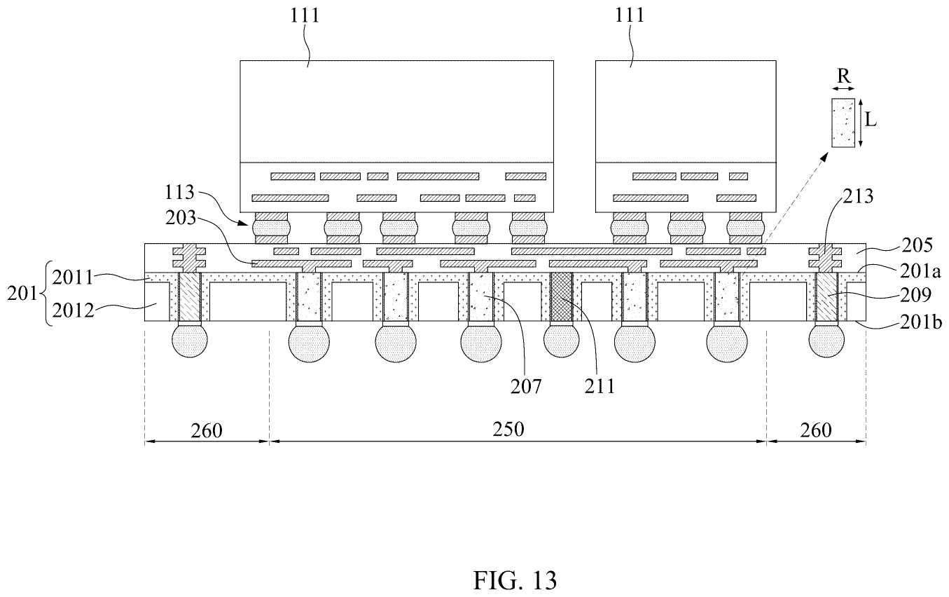

Refer to FIG. 13. FIG. 13 illustrates a cross-sectional view of a semiconductor structure 200 in accordance with some embodiments of the present disclosure. In some embodiments, the thermal conductivity of the second semiconductor portion 2012 of the semiconductor structure 200 may be about 3.3 times of that of the first semiconductor portion 2011 of the semiconductor structure 200. A semiconductor portion with higher thermal conductivity exhibits better heat removal ability. Therefore, the semiconductor structure 200 including the second semiconductor portion 2012 of higher thermal conductivity leads to an improved overall heat dissipation ability. In some embodiments, the first via structure 207 penetrating the substrate 201 of the semiconductor structure 200 may have a length L corresponding to the height H of the substrate 201, and the first via structure 207 may have a bottom area A, wherein the resistance of the first via structure is determined by the following equation: R (resistance)=ρ (resistance factor)*L/A. In some embodiments, in the case that L is decreased while other conditions are the same, the resistance will therefore be decreased as well.

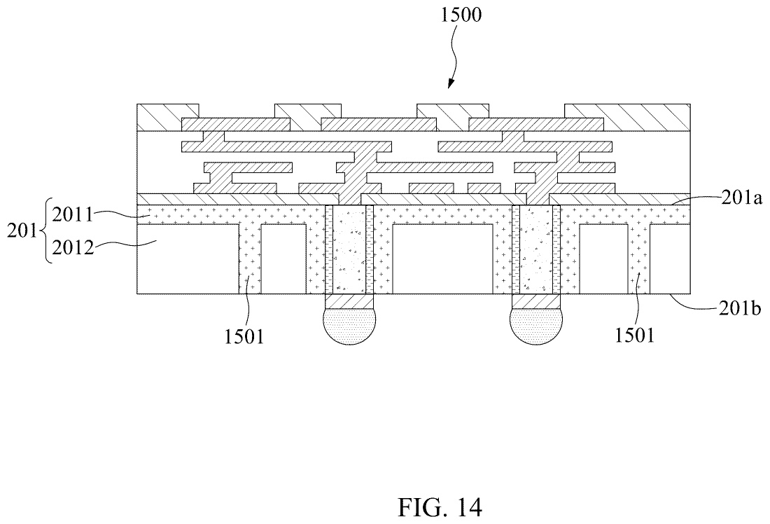

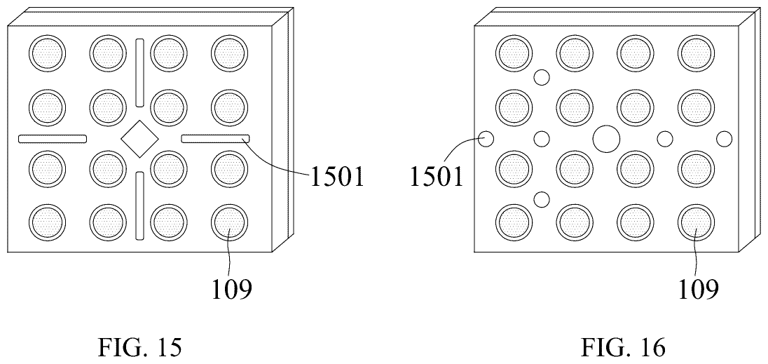

Refer to FIGS. 14 to 16. FIG. 14 illustrates a cross-sectional and partial view of a semiconductor structure 1500 in accordance with some embodiments of the present disclosure, and FIGS. 15 and 16 illustrate different plan views of the back side of semiconductor structures in accordance with some embodiments of the present disclosure. Referring to FIG. 14, in some embodiments, in addition to the configuration disclosed in the semiconductor structure 200, the semiconductor structure 1500 may further include a plurality of third semiconductor portions 1501 in the substrate 201 penetrating from the first surface 201a of the substrate 201 to the second surface 201b of the substrate 201. In some embodiments, the plurality of third semiconductor portions 1501 and the first semiconductor portion 2011 may include the same material. In some embodiments, the third semiconductor portions 1501 are coupled to the first semiconductor portions 2011. Referring to FIGS. 15 and 16, in some embodiments, the third semiconductor portions 1501 disposed in the semiconductor substrate 201 may have a bottom of a shape of a rectangle, a square, or a circle. The third semiconductor portions 1501 are used for balancing the difference between the first semiconductor portion 2011 and the second semiconductor portion 2012 in terms of the thermal expansion.

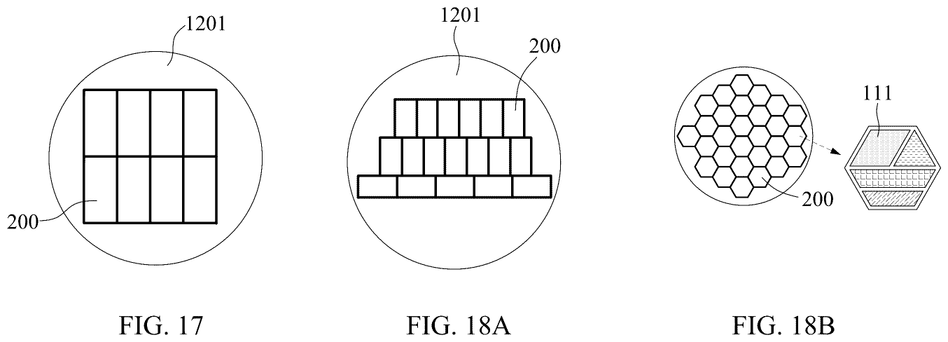

Refer to FIG. 17. FIG. 17 illustrates a plan view of the arrangement of the semiconductor structure 200 on a bottom substrate 1201 in accordance with some embodiments of the present disclosure. Referring to FIG. 17, in some embodiments, the semiconductor structures 200 are arranged on the bottom substrate 1201 in a manner that scribe lines for separating the semiconductor structures 200 are aligned. Referring to FIG. 18A, in some embodiments, the semiconductor structures 200 are arranged in a way that the structure-to-structure spacing window may be interlaced, so that the flexibility of the arrangement of the semiconductor structures 200 are enlarged. Referring to FIG. 18B, in some embodiments, the shape of the semiconductor structures 200 may be a hexagon shape, and the at least one die 111 may have a shape of a rectangle, a square, a trapezoid, a triangle, or a parallelogram. In some embodiments, at least one die 111 of different shapes may be disposed on a semiconductor structure 200.

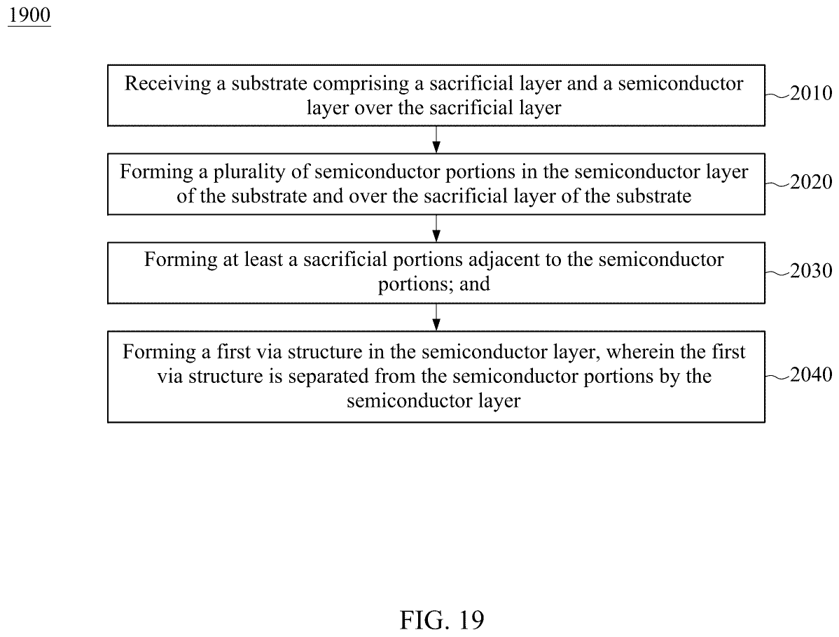

Refer to FIG. 19. FIG. 19 illustrates a flowchart of a method 1900 of forming a semiconductor structure in accordance with some embodiments of the present disclosure. The method 1900 includes a number of operations and will be further described according to one or more embodiments. It should be noted that the operations of the method 1900 may be rearranged or otherwise modified within the scope of the various aspects. It should be further noted that additional processes may be provided before, during, and after the method 1900, and that some other processes may just be briefly described herein. Thus, other implementations are possible within the scope of the various aspects described herein.

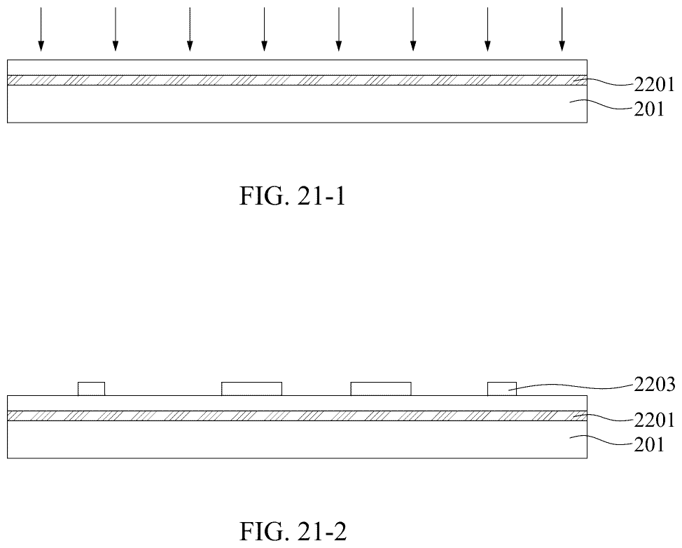

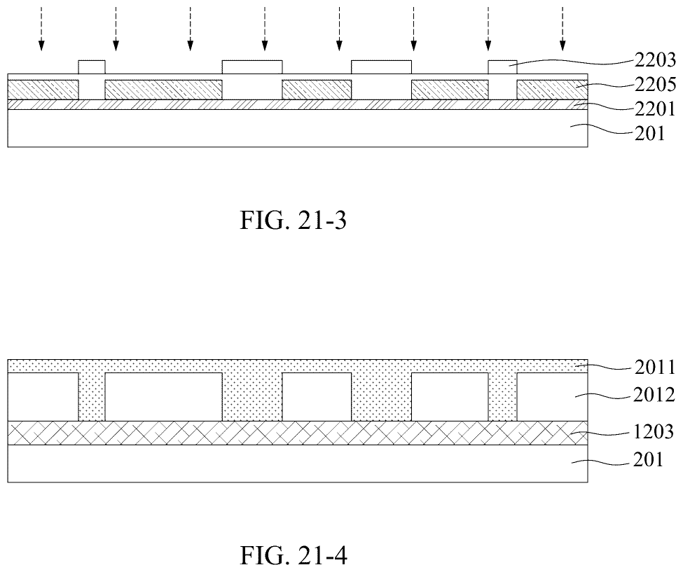

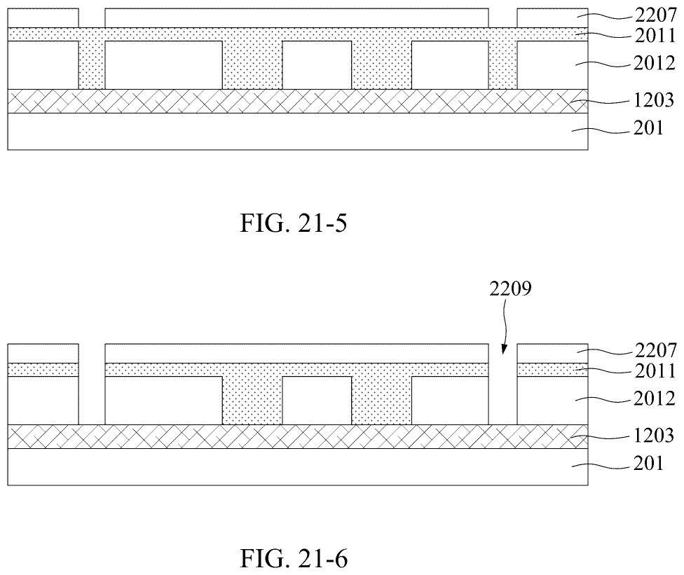

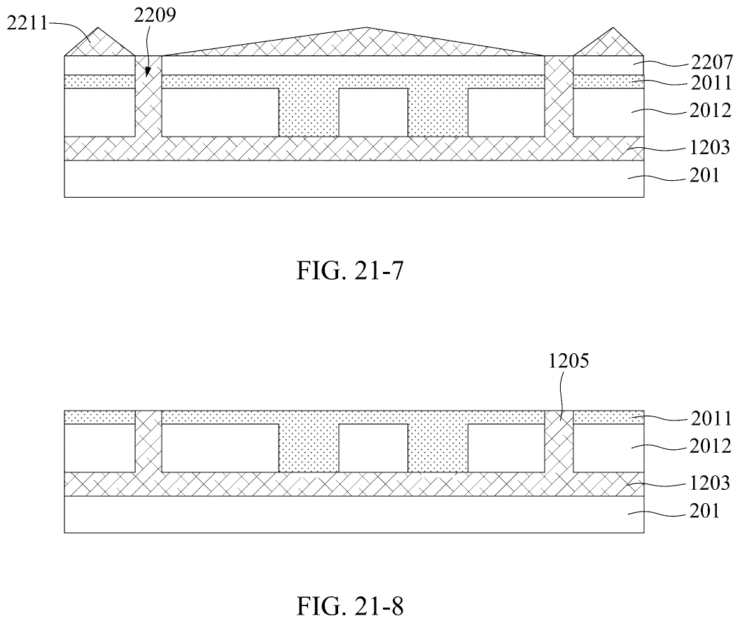

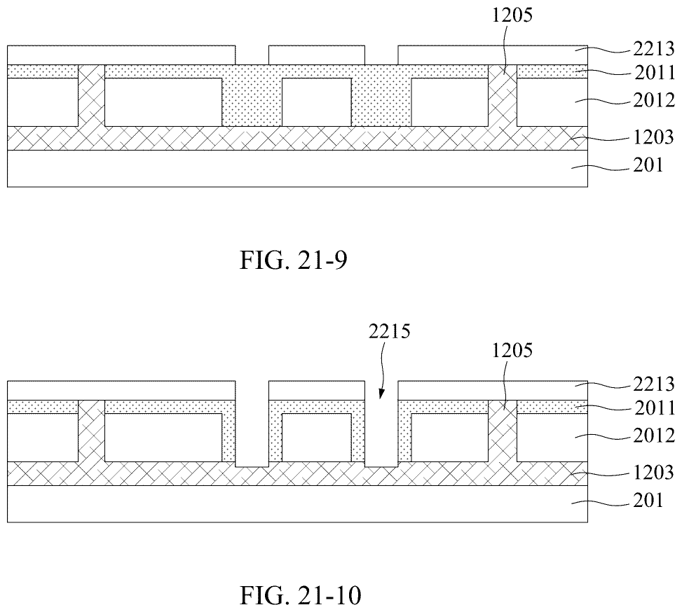

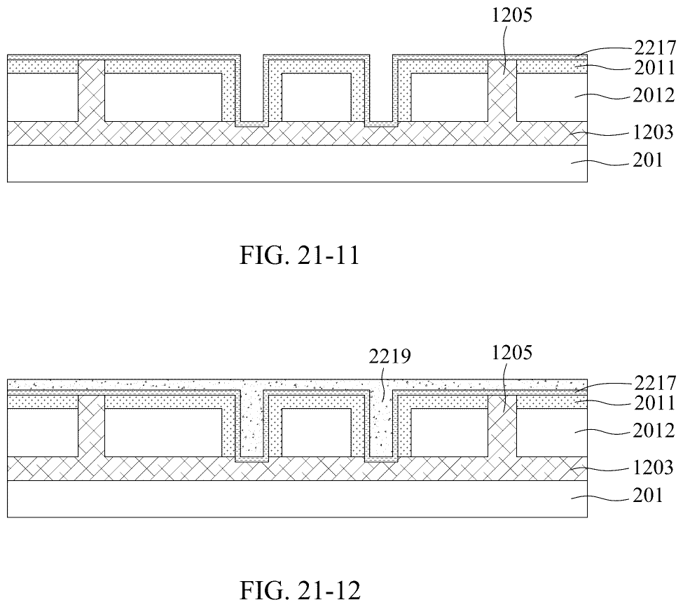

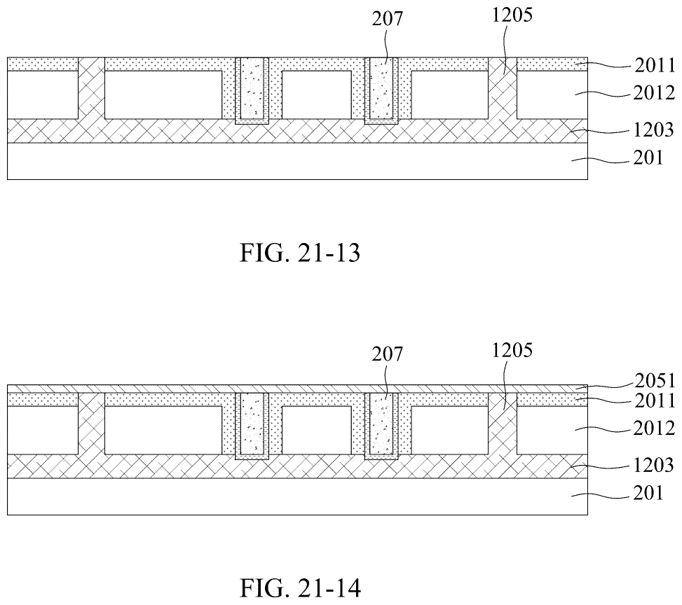

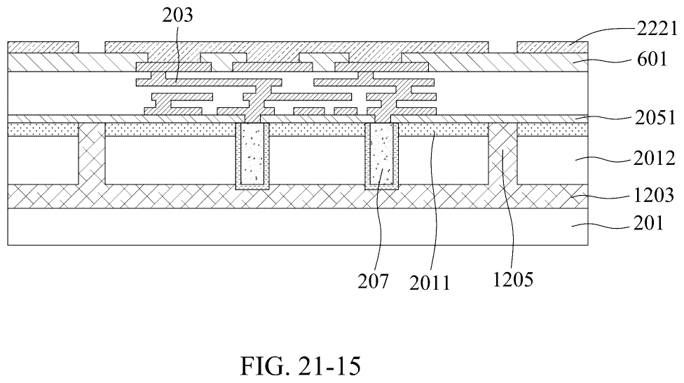

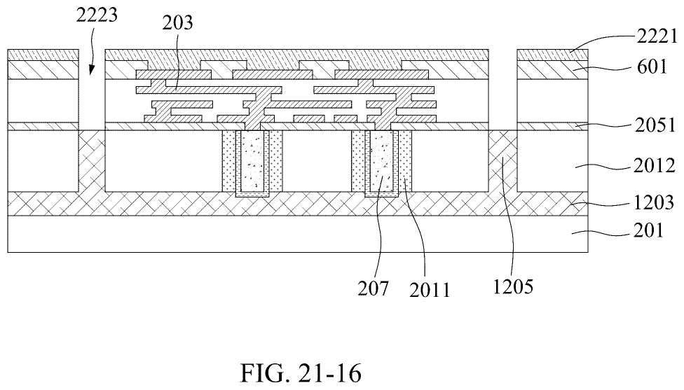

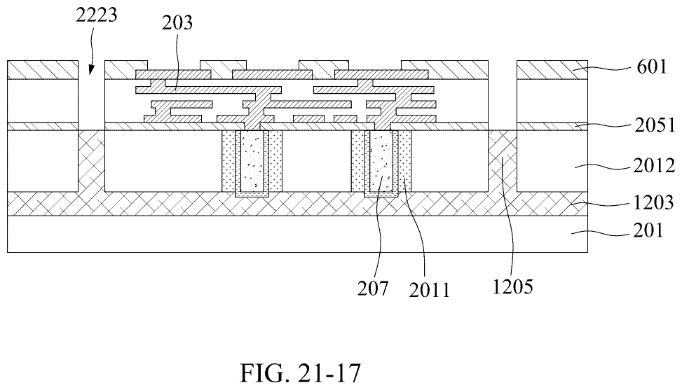

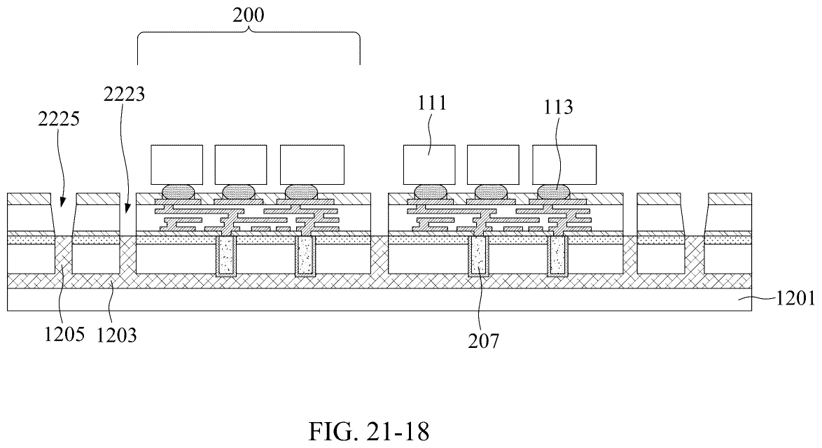

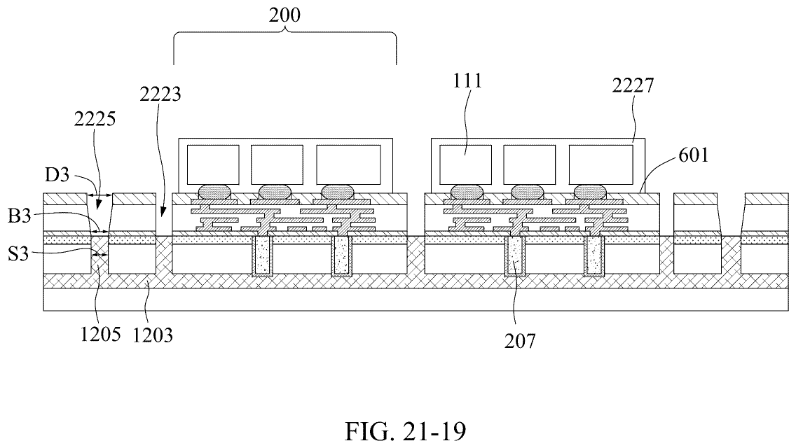

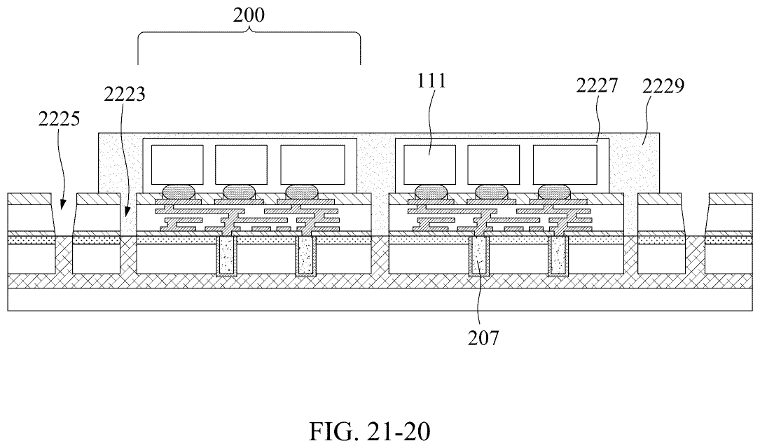

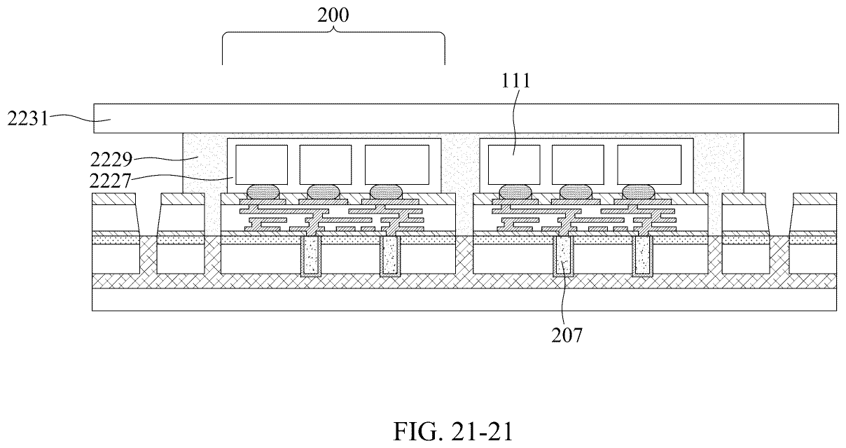

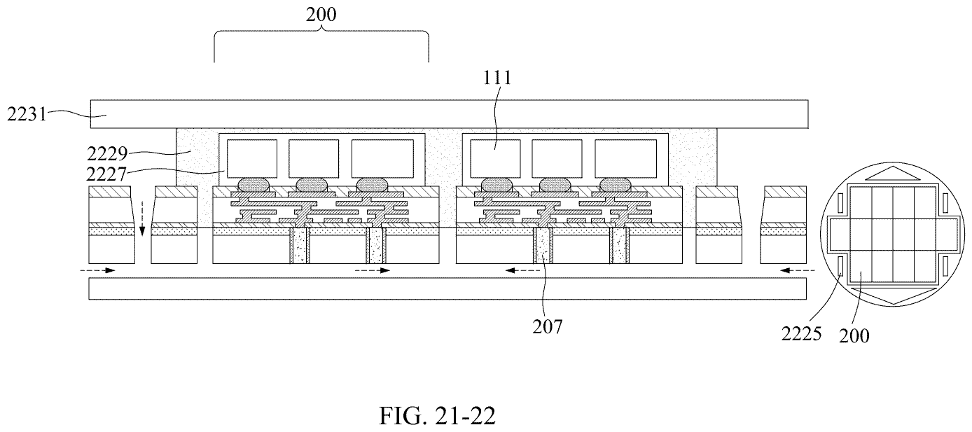

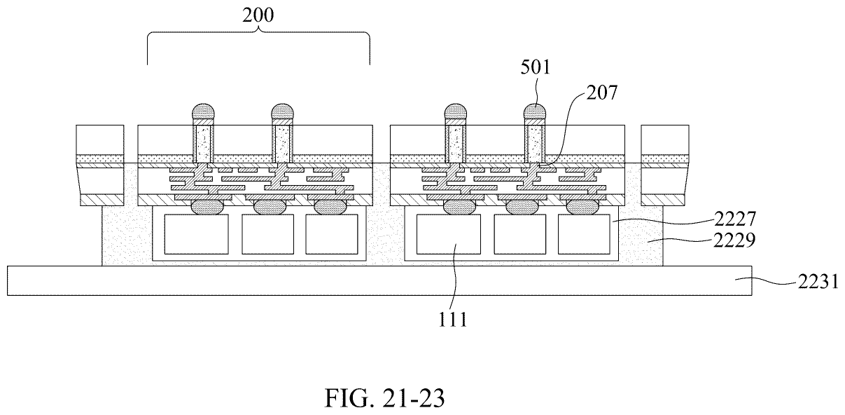

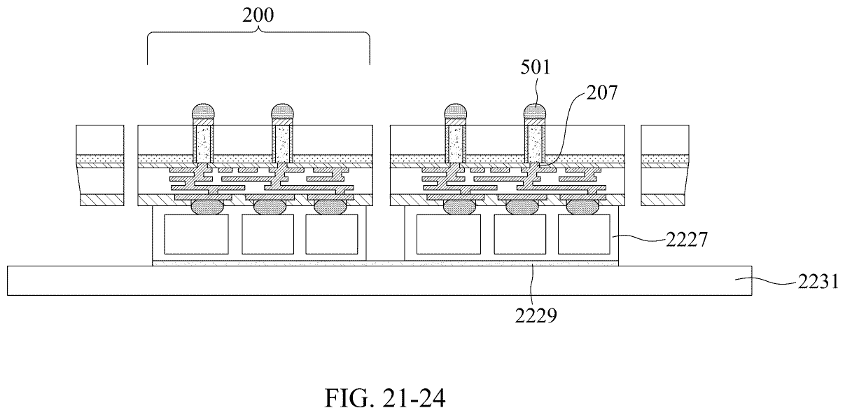

The method 1900 begins with operation 2010 in which a substrate including a sacrificial layer and a semiconductor layer over the sacrificial layer is received. Refer to FIGS. 21-1 to 21-25, which illustrate cross-sectional views of a portion of a semiconductor structure at various stage of formation in accordance with some embodiments of the present disclosure. Referring to FIG. 21-1, in some embodiments, in operation 2010, oxygen may be implanted into a substrate 201 from the first surface 201a of the substrate 201 to form an oxygen-containing layer 2201. In some embodiments, oxygen may be implanted into the substrate 201 at 5*10¹⁴ to 5*10¹⁸ atoms/cm². In some embodiments, oxygen may be implanted into the substrate 201 at a depth of 5 μm to 30 μm.

The method 1900 proceeds with operation 2020 in which a plurality of semiconductor portions are formed in the semiconductor layer of the substrate and over the sacrificial layer of the substrate. Referring to FIG. 21-2, in some embodiments, after the oxygen-containing layer 2201 is formed, a first hard mask film 2203 may be deposited on the first surface 201a of the substrate 201, and the first hard mask film 2203 may be patterned to expose a portion of the first surface 201a of the substrate 201. Referring to FIG. 21-3, in some embodiments, after the first hard mask film 2203 is patterned, carbon may be implanted into the substrate 201 to form a plurality of carbon-containing regions 2205 over the oxygen-containing layer 2201. In some embodiments, the plurality of carbon-containing regions 2205 include silicon and carbon. In some embodiments, carbon may be implanted into the substrate at 2*10¹⁵ to 8*10¹⁸ atoms/cm². In some embodiments, carbon may be implanted into the substrate 201 at a depth of 5 μm to 30 μm.

Referring to FIG. 21-4, in some embodiments, after carbon is implanted into the substrate 201, an annealing operation may be performed to the substrate 201 so that the oxygen-containing layer 2201 is transferred to the sacrificial layer 1203, and the semiconductor layer 2011 is referred to as disposed over the sacrificial layer 1203. The carbon-containing regions 2205 are transferred to the plurality of semiconductor portions 2012 over the sacrificial layer 1203. In some embodiments, the sacrificial layer 1203 includes silicon oxide, and the plurality of semiconductor portions 2012 include silicon carbide. In some embodiments, after the annealing operation is performed, the first hard mask film 2203 is removed from the substrate 201. In some embodiments, the semiconductor layer 2011 may be referred to as a first semiconductor portion 2011, and the semiconductor portion 2012 may be referred to as a second semiconductor portion 2012. Further, the second semiconductor portions 2012 are separated from each other by the first semiconductor portion 2011.

In some embodiments, a silicon-on-insulating (SOI) substrate is received. The SOI substrate includes a sacrificial layer 1203 and a semiconductor layer 2011 formed thereon. The semiconductor portions 2012 may be formed in the semiconductor layer 2011 using the implantation and annealing as mentioned above.

The method 1900 begins with operation 2030 in which at least a sacrificial portion is formed adjacent to the semiconductor portions 2012. Referring to FIG. 21-5, in some embodiments, after the first hard mask film 2203 is removed, a second mask film 2207 may be deposited on the first surface 201a of the substrate 201 and patterned to expose a portion of the first surface 201a of the substrate 201. Referring to FIG. 21-6, in some embodiments, an etching operation may be performed to the substrate 201 through the second mask film 2207 to remove part of the first semiconductor portions 2011 from the substrate 201 to form at least one recess 2209 in the substrate 201. In some embodiments, the sacrificial layer 1203 is exposed through a bottom of the recess 2209, and the semiconductor portions 2012 are exposed through sidewalls of the recess 2209. Referring to FIG. 21-7, in some embodiments, an insulating material 2211 is deposited onto a top surface of the second mask film 2207 and fills the recess 2209 of the substrate 201. In some embodiments, the insulating material 2211 and the sacrificial layer 1203 may include the same material. Referring to FIG. 21-8, in some embodiments, a planarization operation may be performed to remove superfluous insulating material to form the sacrificial portion 1205. In some embodiments, the at least one sacrificial portion 1205 is adjacent to the semiconductor portions 2012 of the substrate 201. In some embodiments, after the planarization operation, the first surface 201a of the substrate 201 and a top surface of the sacrificial portion are co-planar.

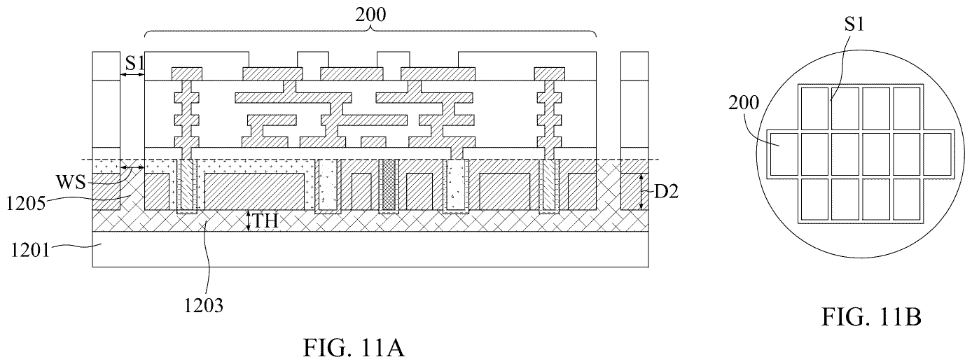

The method 2000 begins with operation 2040 in which a first via structure is formed in the semiconductor layer 2011 (i.e., the first semiconductor portions 2011), wherein the first via structure is separated from the semiconductor portions 2012 by the semiconductor layer 2011. Referring to FIG. 21-9, in some embodiments, a third hard mask film 2213 is formed on the first surface 201a of the substrate 201 and patterned to expose a portion of the first surface 201a of the substrate 201. Referring to FIG. 21-10, in some embodiments, an etch operation is performed to the substrate 201 to remove a portion of the semiconductor layer 2011 through the exposed portion of the first surface of the substrate to form at least one recess 2215 in the semiconductor layer 2011 of the substrate 201, wherein the sacrificial layer 1203 is exposed through a bottom of the recess 2215 and the semiconductor layer 2011 is exposed through sidewalls of the recess 2215. Referring to FIG. 21-11, in some embodiments, a buffer layer 2217 is formed over the sidewall and the bottom of the recess 2215. Referring to FIG. 21-12, in some embodiments, after the buffer layer 2217 is formed over the sidewall and the bottom of the recess 2215, a conductive material 2219 is formed to fill the recess 2215. Referring to FIG. 21-13, in some embodiments, after the recess 2215 is filled with the conductive material 2219, a planarization operation, such as chemical mechanical polishing process, is performed to the substrate 201 so that superfluous conductive material 2219 and buffer layer 2217 are removed to form the first via structure 207. In some embodiments, after the planarization operation, the first surface 201a of the substrate 207 and a top surface of the first via structure 207 are co-planar. Referring to FIG. 21-14, in some embodiments, after the first surface 201a of the substrate 201 and the top surface of the first via structure 207 are planarized, a first dielectric layer 2051 is formed over the first surface 201a of the substrate 201.

In some embodiments, a second via structure 209 may be formed in the substrate 201, wherein the second via structure 209 is separated from the interconnect structure 203 and the first via structure 207. In some embodiments, a third via structure may be formed in the substrate 201, wherein the third via structure is separated from the interconnect structure 203, the first via structure 207 and the second via structure 209. In some embodiments, the second via structure 209 and the third via structure may be formed simultaneously with the first via structure 207.

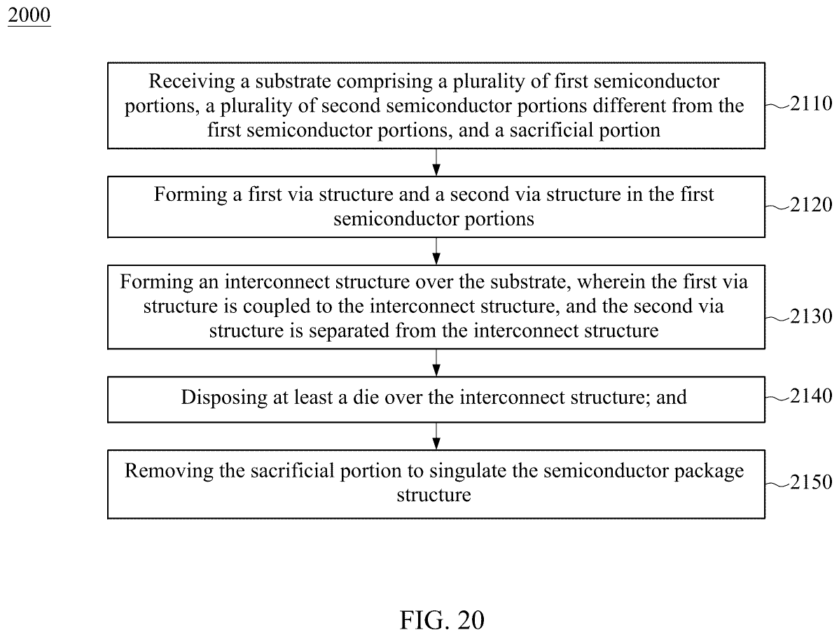

Refer to FIG. 20. FIG. 20 illustrates a flowchart of a method 2000 of forming a semiconductor structure in accordance with some embodiments of the present disclosure. The method 2000 includes a number of operations and will be further described according to one or more embodiments. It should be noted that the operations of the method 2000 may be rearranged or otherwise modified within the scope of the various aspects. It should be further noted that additional processes may be provided before, during, and after the method 2000, and that some other processes may just be briefly described herein. Thus, other implementations are possible within the scope of the various aspects described herein.

The method 2000 begins with operation 2110 in which a substrate including a plurality of first semiconductor portions 2011, a plurality of second semiconductor portions 2012 different from the first semiconductor portions 2011, and a sacrificial portion 1203 is received, as shown in FIG. 21-5. The method proceeds with operation 2120, in which a first via structure 207 and a second via structure 209 are formed in the first semiconductor portions 2011. Referring to FIGS. 21-9 to 21-14, in some embodiments, the first via structure 207 and a second via structure (not shown) may be simultaneously formed in the first semiconductor portions 2012. The method 2000 proceeds with operation 2130, in which an interconnect structure 203 is formed over the substrate 201, wherein the first via structure 207 is coupled to the interconnect structure 203, and the second via structure 209 is separated from the interconnect structure 203. In some embodiments, the second via structure 209 is coupled to a second interconnect structure 213 separated from the interconnect structure 203, as shown in FIG. 2.

Referring to FIG. 21-15, in some embodiments, a passivation layer 601 is formed over the interconnect structure 203. In some embodiments, a fourth mask film 2221 may be formed on a top surface of the interconnect structure 203, and is patterned to expose a portion of the top surface of the interconnect structure 203.

Referring to FIG. 21-16, in some embodiments, an etch process is performed to remove a portion of interconnect structure 203 to form at least one recess 2223, wherein the sacrificial portion 1205 is exposed through a bottom of the recess 2223. In some embodiments, at least one sacrificial layer removal recess 2225 (shown in FIG. 21-18) may be formed simultaneously with the formation of the at least one recess 2223. Refer to FIGS. 11A and 11B. FIG. 11A illustrates a cross-sectional view of a wafer-level view of a plurality of semiconductor structures 200 in accordance with some embodiments of the present disclosure. FIG. 11B illustrates a plan view of a wafer-level view of a plurality of semiconductor structures 200 in accordance with some embodiments of the present disclosure. In some embodiments, a plurality of semiconductor structures 200 are coupled to a bottom substrate 1201 through a horizontal sacrificial layer 1203. The horizontal sacrificial layer 1203 has a thickness TH of greater than 0.2 micrometers. In some embodiments, the horizontal sacrificial layer 1203 may include a semiconductor material. In some embodiments, the horizontal sacrificial layer 1203 may include a silicon-containing material. In some embodiments, the silicon-containing material may include a silicon oxide. In some embodiments, the plurality of semiconductor structures 200 on the bottom substrate 1201 are partially connected to each other by a vertical sacrificial layer 1205. In some embodiments, the vertical sacrificial layer 1205 and the horizontal sacrificial layer 1203 may include the same material. In some embodiments, the vertical sacrificial layer 1205 may include a width WS greater than 0.2 micrometers. In some embodiments, the plurality of semiconductor structures 200 are partially separated from each other at a distance greater than 0.05 micrometers. In some embodiments, the second semiconductor portion 2012 has a thickness D2 of 0.3 micrometers or more. In some embodiments, as shown in FIG. 11B, the lines between the semiconductor structures 200 refer to the distance S1 between the plurality of semiconductor structures as shown in FIG. 11A. In some embodiments, the distance S1 is the die spacing window of each semiconductor structure 200. In some embodiments, S1 is greater than 0.05 micrometers.

Referring to FIG. 21-17, in some embodiments, after the recess is formed, the fourth mask film 2221 may be removed to expose the top surface of the passivation layer 601. In some embodiments, the fourth mask film 2221 may be removed by an etching process.

Refer to FIG. 21-18. The method 2000 proceeds with operation 2140 in which at least a die is disposed over the interconnect structure 203. FIG. 21-18 illustrates a schematic wafer-level view of multiple semiconductor structures 200 on a bottom substrate 1201 before being separated. Referring to FIG. 21-18, in some embodiments, the at least one die 111 is coupled to the semiconductor structures 200 by at least one external connection feature 113 disposed between the interconnect structure 203 of the semiconductor structure 200 and the at least one die 111.

Referring to FIG. 21-19, in some embodiments, after the at least one die 111 is disposed over the interconnect structure 203, a filling material 2227, such as underfills, may be formed over the at least one die 111. In some embodiments, the filling material 2227 covers top surface and sidewalls of the at least one die 111, and at least a portion of the passivation layer 601. In some embodiments, the filling material 2227 is then molded so that the shape of the filling material 2227 formed over the at least one die 111 is fixed.

Referring to FIG. 21-19, the at least one sacrificial layer removal recess 2225 may include a top width D3 and a bottom width B3, wherein D3 is greater than or equal to B3. The at least one sacrificial layer removal recess 2225 may be the window for removing the sacrificial layer 1203 and the sacrificial portion 1205. In some embodiments, the sacrificial portion 1205 may have a width S3, wherein B3 is greater than or equal to S3. In some embodiments, S3 is greater than 0.2 micrometers.

Referring to FIG. 21-20, in some embodiments, after the filling material 2227 is formed over the at least one die 111, a protection layer 2229 may be formed over the at least one die 111 to cover the filling material 2227 and fill the at least one recess 2223. As shown in FIG. 21-20, the sacrificial layer removal recess 2225 is free of the protection layer 2229. In some embodiments, the protection layer 2229 may be coated over the at least one die 111. In some embodiments, the protection layer 2229 may include a glue-like material so that when the protection layer 2229 is formed over the at least one die 111, the protection layer 2229 will be fixed on the at least one die 111.

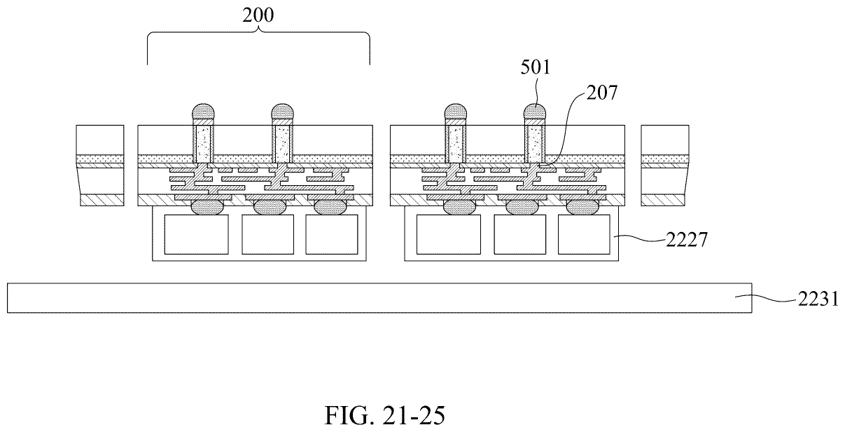

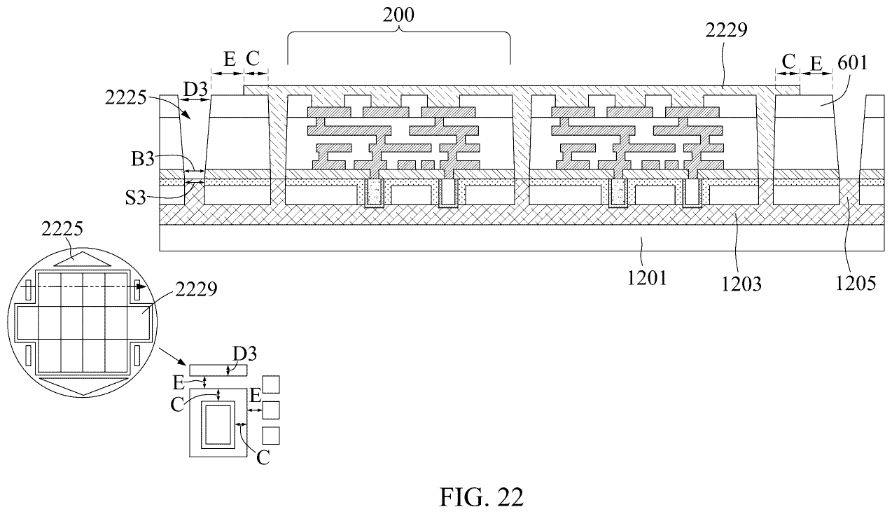

Referring to FIG. 21-21, in some embodiments, after the protection layer 2229 is formed over the at least one die 111, a carrier substrate 2231 may be attached to the protection layer 2229. In some embodiments, the protection layer 2229 may serve as an adhesive layer for bonding the semiconductor structure 200 and the carrier substrate 2231. Referring to FIG. 21-22, in some embodiments, after the carrier substrate 2231 is attached to the protection layer 2229, the sacrificial portion 1205 and the sacrificial layer 1203 may be removed. In some embodiments, the sacrificial portion 1205 is removed prior to the removal of the sacrificial layer 1203. In some embodiments, the sacrificial portion 1205 and the sacrificial layer 1203 are simultaneously removed. In some embodiments the sacrificial portion 1205 and the sacrificial layer 1203 are removed by a cleaning process. In some embodiments, after the sacrificial portion 1205 and the sacrificial layer 1203 are removed, the semiconductor structures are detached from the bottom substrate 1201. FIG. 21-22 also shows a plan view of a plurality of semiconductor structures 200 on the bottom substrate 1201, wherein the at least one sacrificial layer removal recess 2225 surround the periphery of the bottom substrate 1201.

Referring to FIG. 21-23, in some embodiments, after the sacrificial portion 1205 and the sacrificial layer 1203 are removed and the semiconductor structures 200 are detached from the bottom substrate 1201, the semiconductor structures 200 and the attached carrier substrate 2231 are flipped so that the second surface 201b of the substrate 201 of the semiconductor structures 200 are facing upward, and the bottom of the at least one first via structure 207 is exposed.

Referring to FIG. 21-23, in some embodiments, at least one external terminal 501 may be formed over and coupled to the first via structure 207. Additionally, the external terminal 501 may be formed over and coupled to the second via structure 209 and/or the third via structure 211, though not shown.

Referring to FIG. 21-24, in some embodiments, the protection layer 2229 is partially removed so that the periphery of the at least one semiconductor structure 200 is exposed, while the protection layer 2229 between the carrier substrate 2231 and the filling material 2227 is retained. In some embodiments, the protection layer 2229 is removed by a cleaning process.

Referring to FIG. 21-25, in some embodiments, the protection layer 2229 between the carrier substrate 2231 is removed to singulate the semiconductor structures 200.

Refer to FIG. 22. FIG. 22 illustrates a cross-sectional view of a plurality of semiconductor substrates 200 disposed on a bottom substrate 1201 in accordance with some embodiments of the present disclosure. FIG. 22 omits the attachment of the at least one die 111 as disclosed in the aforementioned figures. In some embodiments, the protection layer 2229 is separated from the at least one sacrificial layer removal recess 2225. The protection layer 2229 may include polyimide or a protect glue. In some embodiments, a distance E between the protection layer 2229 and sidewall of the at least one sacrificial layer removal recess 2225 is >5 μm. In some embodiments, the protection layer 2229 over the passivation layer 601 adjacent to the at least one sacrificial layer removal recess 2225 includes a width C of 10 micrometers or more. The at least one sacrificial layer removal recess 2225 may include a top width D3 and a bottom width B3, wherein D3 is greater than or equal to B3. The at least one sacrificial layer removal recess 2225 may be the window for removing the sacrificial layer 1203 and the sacrificial portion 1205. In some embodiments, the sacrificial portion 1205 may have a width S3, wherein B3 is greater than or equal to S3. In some embodiments, S3 is greater than 0.2 micrometers.

In the present disclosure, a semiconductor structure including a substrate, an interconnect structure, a first via structure and a second via structure is provided. The substrate includes a first surface and a second surface opposite to the first surface, wherein the substrate includes a first semiconductor portion and a second semiconductor portion different from the first semiconductor portion. The interconnect structure is over the first surface of the substrate. The first via structure penetrates the substrate from the first surface to the second surface, and is coupled to the interconnect structure. The second via structure penetrates the substrate from the first surface to the second surface, and is separated from the interconnect structure and the first via structure. The second semiconductor portion of the substrate provides higher thermal conductivity and higher hardness than those of the first semiconductor portion of the substrate. Therefore, the substrate may be designed in a thinner manner so as to reduce the resistance of the first via structures. In addition, with the presence of the second via structures in the semiconductor structures, heat generated during the operation of the semiconductor structures can be dissipated through the second via structures, thus the overall heat dissipation performance of the semiconductor structures are increased.

In the present disclosure, a semiconductor structure including a substrate, an interconnect structure, a first via structure and a second via structure is provided. The substrate includes a first surface and a second surface opposite to the first surface, wherein the substrate includes a first semiconductor portion and a second semiconductor portion different from the first semiconductor portion. The interconnect structure is over the first surface of the substrate. The first via structure penetrates the substrate from the first surface to the second surface, and is coupled to the interconnect structure. The second via structure penetrates the substrate from the first surface to the second surface, and is separated from the interconnect structure and the first via structure.

In some embodiments, a method of forming a semiconductor structure is provided. The methods includes following operations. A substrate comprising a sacrificial layer and a semiconductor layer over the sacrificial layer is received. A plurality of semiconductor portions are formed in the semiconductor layer of the substrate and over the sacrificial layer of the substrate. At least a sacrificial portions are formed adjacent to the semiconductor portions. A first via structure is formed in the semiconductor layer, wherein the first via structure is separated from the semiconductor portions by the semiconductor layer.

In some embodiments, a method of forming a semiconductor package structure is provided. The methods includes following operations. A substrate comprising a plurality of first semiconductor portions, a plurality of second semiconductor portions different from the first semiconductor portions, and a sacrificial portion is received. A first via structure and a second via structure are formed in the first semiconductor portions. An interconnect structure over the substrate, wherein the first via structure is coupled to the interconnect structure, and the second via structure is separated from the interconnect structure. At least a die is disposed over the interconnect structure. The sacrificial portion is removed to singulate the semiconductor package structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a substrate having a first surface and a second surface opposite to the first surface, wherein the substrate comprises a first semiconductor portion and a second semiconductor portion different from the first semiconductor portion;
an interconnect structure over the first surface of the substrate;
a first via structure penetrating the substrate from the first surface to the second surface, and coupled to the interconnect structure; and
a second via structure penetrating the substrate from the first surface to the second surface, and separated from the interconnect structure and the first via structure.

2. The semiconductor structure of claim 1, wherein a Moh's hardness of the second semiconductor portion is different than a Moh's hardness of the first semiconductor portion.

3. The semiconductor structure of claim 1, wherein the second via structure is separated from the second semiconductor portion by the first semiconductor portion.

4. The semiconductor structure of claim 1, wherein the first via structure is disposed in a central region of the substrate, and the second via structure is disposed in a peripheral region of the substrate.

5. The semiconductor structure of claim 1, further comprising a third via structure disposed in the central region of the substrate, wherein the third via structure penetrates the substrate from the first surface to the second surface, and is separated from the first via structure and the interconnect structure.

6. The semiconductor structure of claim 1, wherein the second semiconductor portion is separated from the interconnect structure by the first semiconductor portion.

7. The semiconductor structure of claim 1, wherein the second semiconductor portion is in contact with the interconnect structure.

8. The semiconductor structure of claim 1, wherein the second semiconductor portion is exposed through the second surface.

9. The semiconductor structure of claim 1, wherein a top surface and a bottom surface of the second semiconductor portion are in contact with the first semiconductor portion.

10. The semiconductor structure of claim 1, further comprising at least a die disposed over the first surface of the substrate and coupled to the interconnect structure.

11. A method for forming a semiconductor structure, comprising:
receiving a substrate comprising a sacrificial layer and a semiconductor layer over the sacrificial layer;
forming a plurality of semiconductor portions in the semiconductor layer of the substrate and over the sacrificial layer of the substrate;
forming at least a sacrificial portions adjacent to the semiconductor portions; and
forming a first via structure in the semiconductor layer, wherein the first via structure is separated from the semiconductor portions by the semiconductor layer.

12. The method of claim 11, further comprising:
implanting oxygen into the substrate to form an oxygen-containing layer;
implanting carbon into the substrate to form a plurality of carbon-containing regions over the oxygen-containing layer; and
transferring the oxygen-containing layer to the sacrificial layer and the carbon-containing regions to the semiconductor portions over the sacrificial layer.

13. The method of claim 11, wherein the forming of the sacrificial portion further comprises:
removing a portion of the semiconductor layer to form a recess, wherein the sacrificial layer is exposed through a bottom of the recess, and the semiconductor portions are exposed through sidewalls of the recess;
filling the recess with an insulating material; and
removing superfluous insulating material to form the sacrificial portion.

14. The method of claim 11, wherein the forming of the first via structure further comprising:
removing a portion of the semiconductor layer to form a recess, wherein the sacrificial layer is exposed through a bottom of the recess, and the semiconductor layer is exposed through sidewalls of the recess;
filling the recess with a conductive material; and
removing superfluous conductive material to form the first via structure.

15. The method of claim 11, further comprising forming an interconnect structure over the substrate, wherein the first via structure is coupled to the interconnect structure.

16. The method of claim 15, further comprising forming a second via structure in the semiconductor layer, wherein the second via structure is separated from the interconnect structure and the first via structure.

17. A method for forming a semiconductor package structure, comprising:
receiving a substrate comprising a plurality of first semiconductor portions, a plurality of second semiconductor portions different from the first semiconductor portions, and a sacrificial portion;
forming a first via structure and a second via structure in the first semiconductor portions;
forming an interconnect structure over the substrate, wherein the first via structure is coupled to the interconnect structure, and the second via structure is separated from the interconnect structure;
disposing at least a die over the interconnect structure; and
removing the sacrificial portion to singulate the semiconductor package structure.

18. The method of claim 17, wherein the removing of the sacrificial portion further comprises:
forming a protection layer over the die;
attaching the protection layer to a carrier substrate;
removing the sacrificial portion; and
removing the protection layer and the carrier substrate.

19. The method of claim 17, further comprising forming at least an external terminal coupled to the first via structure after the removing of the sacrificial portion.

20. The method of claim 17, wherein a Moh's hardness of the second semiconductor portion is different than a Moh's hardness of the first semiconductor portion.
